(19) United States
(12) Patent Application Publication
(10) Pub. No.: US 2010/0109743 A1
(43) Pub. Date: May 6, 2010

(54) LEVEL SHIFTER HAVING NATIVE TRANSISTORS

(76) Inventors: Martin Czech, Eschbach (DE); Juergen Giehl, Kirchzarten (DE); Ulrich Theus, Freiburg (DE)

Correspondence Address: Patrick J. O'Shea, Esq.;O'Shea Getz P.C., Suite 912, 1500 Main Street, Springfield, MA, 01115, US

(21) Appl. No.: 12/613,901

(22) Filed: Nov. 6, 2009

(30) Foreign Application Priority Data
Nov. 6, 2008 (DE) 10 2008 056 131.2

(51) Int. Cl. H03L 5/00

(52) U.S. Cl. 327/333

(57) ABSTRACT

A level shifter for converting an input signal (in) from a first operating voltage range (I) having a first ground potential (VSS1) and a first operating potential (VDD1) in a second operating voltage range (II) having a second ground potential (VSS2) and a second operating potential (VDD2), having an input circuit to which the input signal (in) may be applied and an output circuit at which the output signal (out) may be picked off, the input circuit having at least one native transistor.

### PRIORITY INFORMATION

This patent application claims priority from German Patent Application No. 10 2008 056 131.2 filed Nov. 6, 2008, which is hereby incorporated by reference in its entirety.

### BACKGROUND OF THE INVENTION

The present invention relates to electronic circuits, and in particular to level shifter circuits.

Level shifters of this type are known from the related art, for example, from German Patent DE 10 2004 052 092 A1 for converting an input signal in from a first operating voltage range I having a first ground potential VSS1 and a first supply potential VDD1 into an output signal out in a second operating voltage range II having a second ground potential VSS2 and a second supply potential VDD2.

FIGS. 3 and 4 schematically illustrate prior art level shifters.

FIG. 3 is a schematic illustration of a prior art level shifter 300 is a first input transistor T1 302 and a first output transistor T3 304 with a series circuit of a second input transistor T2 306 and a second output transistor T4 308 and is connected between first ground potential VSS1 310 and second supply potential VDD2 312. The first output transistor T3 304 and the second output transistor T4 308 are cross-coupled, i.e., a control input of the first output transistor T3 304 is connected to a junction point between the second input transistor T2 306 and the second output transistor T4 308, and a control input of the second output transistor T4 308 is connected to a junction point between the first input transistor T1 302 and the first output transistor T3 304. Input signal in on line 314 may be directly supplied to a control input of the first input transistor T1 302, while it may be supplied to a control input of the second input transistor T2 306 as an inverted input signal inq on line 316. An output signal out on line 318 may be picked off at the junction point between the second input transistor T2 and the second output transistor T4, while an inverted output signal outq on line 320 may be picked off at the junction point between the first input transistor T1 and the first output transistor T3.

If, for example, a high signal is applied on the line 314, the first input transistor T1 is switched to a conducting state and raises the downstream junction point to the first ground potential VSS1. The second input transistor T2, to which the inverted high signal, i.e., a low signal, is supplied, becomes non-conductive. The first ground potential VSS1, applied to the junction point between the first input transistor T1 and the first output transistor T3, switches the second output transistor T4, which is designed as a p-channel transistor, into a conducting state, so that the junction point between the second input transistor T2 and the second output transistor T4 is raised to the second supply potential VDD2. The potential applied to the junction point brings the first output transistor T3, which is also designed as a p-channel transistor, into a blocking state. On the output side, a high signal, namely, the second supply potential VDD2, may thus be picked off at the junction point between the second input transistor T2 and the second output transistor T4 as the output signal out on the line 318. On the output side, at the junction point between the first input transistor T1 and the first output transistor T3, a low signal, namely the first ground potential VSS1, may be picked off as inverted output signal outq on line 320.

If first operating voltage range I is in a range from 0 V to 3 V, for example, and second operating voltage range II is in a range of 7 V to 12 V, it is also necessary, as FIG. 4 shows, to replace each input transistor T1, T2 with a cascode circuit made up of first transistors T11, T21 402, 404 and second transistors T12, T22 406, 408 for surge protection. The control inputs of the second transistors T12, T22 406, 408 are connected to the first supply potential VDD1, so that the two second transistors T12, T22 406, 408 designed as n-channel transistors, are permanently in a conducting state. The two first transistors T11, T21 402, 404 are technologically designed in such a way that they do not overcome the high potential difference between the first ground potential VSS1 and the second supply potential VDD2 without being damaged. This disadvantage is eliminated by the second transistors T12, T22 406, 408.

If, in a level shifter according to the prior art, a potential difference in first operating voltage range I is so small that a resulting effective gate voltage Veff_{G} is in the proximity of threshold voltage Vₜₕ of the input transistors T11 and T21 402, 404, and no transistors having a lower threshold voltage Vₜₕ, which is achieved by a thinner gate oxide and a suitable channel doping, can be used, the level shifter known from the prior art will not operate, since the effective gate voltage of the cascode transistors T12, T22 406, 408 is no longer high enough. Effective gate voltage Veff_{G} is defined as the difference between an actually applied gate-source voltage V_{Gs} and threshold voltage Vₜₕ of a transistor.

There is a need for a level shifter that operates reliably even in the case of a low potential difference in the first operating voltage range I and a high potential difference in the second operating voltage range II.

### SUMMARY OF THE INVENTION

A level shifter according to an aspect of the present invention converts an input signal from a first operating voltage range having a first ground potential and a first operating potential into an output signal in a second operating voltage range having a second ground potential and a second operating potential has an input circuit to which the input signal can be applied and an output circuit at which the output signal may be picked off, wherein the input circuit has at least one native transistor.

An advantage of using native transistors in the input circuit is that they can be appropriately dimensioned in a manufacturing process, that they are appropriate for large voltage differences on its load path while they exhibit low threshold voltage. Native transistors may be manufactured without additional threshold voltage implantation in the channel area and thus exhibit a natural threshold voltage in the manufacturing process. This natural threshold voltage is typically around 0 V.

Using native transistors in the input circuit facilitates level shifters that are switched using little voltage difference in the first supply voltage range and a large voltage difference in the second supply voltage range.

The input circuit of the level shifter preferably has two parallel input stages, each of which has at least one native transistor. For example, the input stages can be designed as cascode circuits having a first transistor and a second transistor in cascode, where the first transistor is suited for the first operating voltage range, and the second transistor is suited for the second operating voltage range and is designed as a native transistor.

The native transistors included in the cascode circuit in the gate layer facilitates that the lowering of the first transistors does not reach the second supply potential thereby protecting the latter from permanent damage. By configuring the native transistor for the second operating voltage range, these withstand the voltage difference without damage and can be made conductive using the first supply potential due to their low threshold voltage. An aspect of the present invention is that an effective gate voltage that is defined as the difference between a gate-source voltage and a threshold voltage of a transistor is available also in the first operating voltage range because of the transistor's decreased threshold voltage.

A connection node between the first and second transistors may clamp to the first supply potential. Such a clamping may be carried out by a third transistor connected as a diode which is designed, for example, as a p-channel transistor or a diode. If, for example, a p-channel transistor connected as a diode is used for clamping, the first and the third transistors of the input stage may be connected as inverters.

To avoid leakage current from the second operating voltage range to the first operating voltage range, the cascode circuits may each include a fourth transistor connected between the first transistor and the second transistor. A control terminal of the fourth transistor, which may be designed as an n-channel transistor, is connected to the first supply potential so that a cascode circuit having two n-channel transistors and a native transistor is formed. Because of the decrease in their threshold voltage, the fourth transistors prevent a connection node of the first and third transistor from being pulled to the potential of the first supply potential thus limiting the leakage current between the first and second operating potential to a few microamperes.

The input circuit and/or the output circuit may have different protective circuits for protection against electrostatic damage. For example, to prevent excessive voltages between the first ground potential and the second ground potential, a circuit that includes two diodes connected in antiparallel or transistors connected as diodes may be provided. Furthermore, a potential difference in the first operating voltage range may be limited by a first operating voltage clamping circuit, and a potential difference in the second operating voltage range may be limited by a second clamping circuit, each of which is situated between the ground potential and the supply potential. The output signal may be furthermore limited to the second operating voltage range by clamping diodes or by transistors connected as diodes, so that no damaging voltages may be applied to the output.

The level shifter according to an aspect of the invention is suited in particular for operating voltage ranges in which a difference between the first operating potential and the first ground potential is in the range of the threshold voltage of the first transistors because it is under such voltage conditions where the level shifters of the prior art no longer work satisfactorily.

It is especially appropriate to build the level shifter from MOS transistors, wherein the output circuit is made up of two cross-coupled MOS transistors.

These and other objects, features and advantages of the present invention will become more apparent in light of the following detailed description of preferred embodiments thereof, as illustrated in the accompanying drawings.

### BRIEF DESCRIPTION OF THE DRAWINGS

FIG. 1 is a schematic illustration of a level shifter according to an aspect of the invention;

FIG. 2 is a schematic illustration of an alternative embodiment of a level shifter according to an aspect of the present invention, extended with respect to FIG. 1;

FIG. 3 is a schematic illustration of a prior art level shifter; and

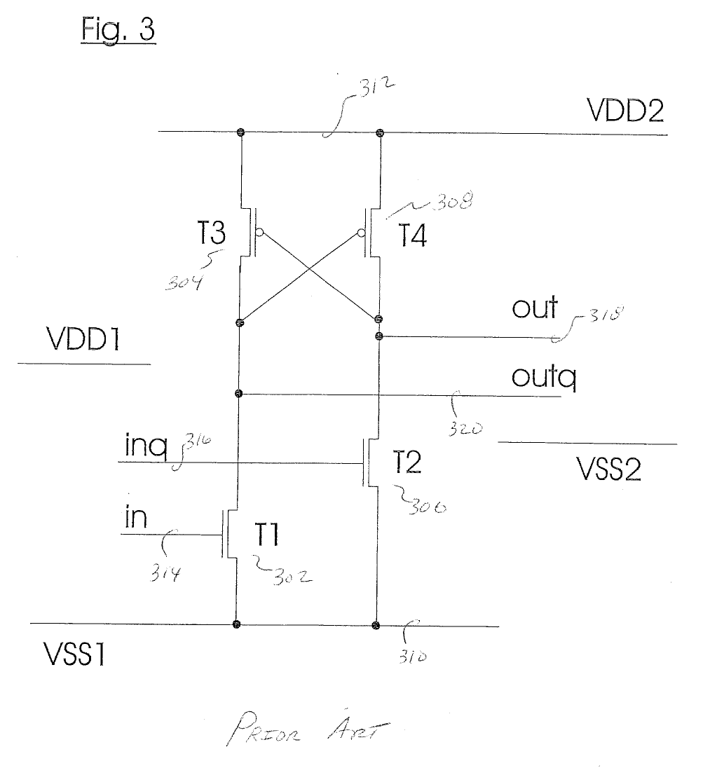

FIG. 4 is a schematic illustration of a prior art level shifter having a cascode circuit.

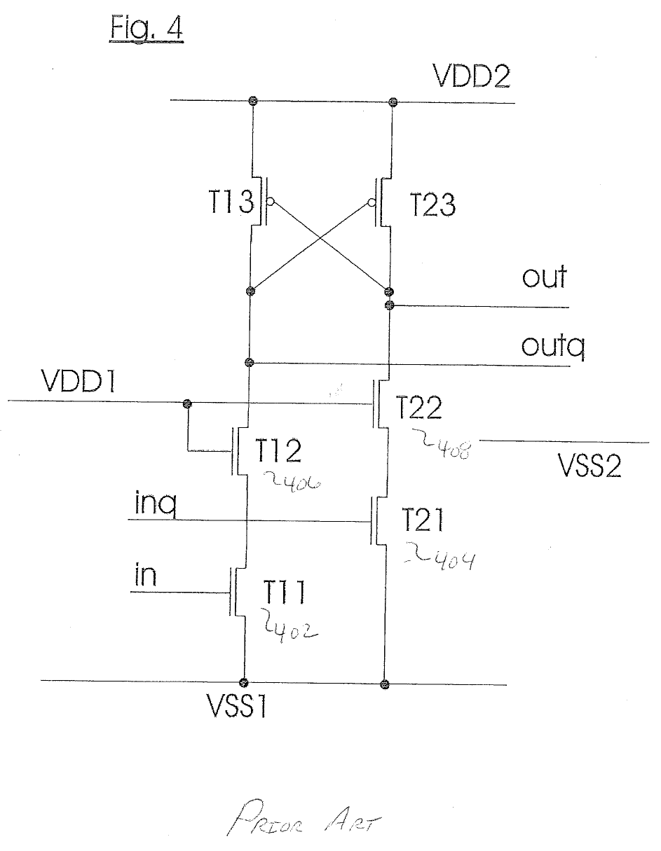

### DETAILED DESCRIPTION OF THE INVENTION

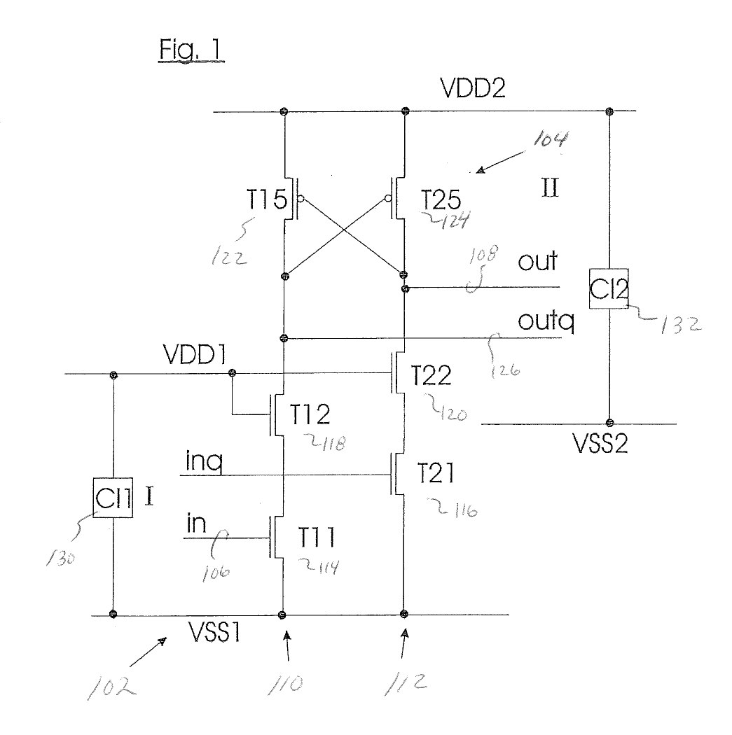

FIG. 1 is a schematic illustration of a level shifter 100 having an input circuit section 102 and an output circuit section 104 for converting an input signal in on a line 106 from a first operating voltage range I into an output signal out on a line 108 in a second operating voltage range II. The first operating voltage range I has a first ground potential VSS1 and a first operating potential VDD1. The second operating voltage range has a second ground potential VSS2 and a second operating potential VDD2. The input circuit 102 is designed as a parallel circuit that includes input stages 110 and 112, each having, as cascode circuits, a first transistor T11, T21 114, 116 in the source circuit and a second transistor T12, T22 118, 120 in the gate circuit. The input signal in on the line 106 can be supplied to one of the two transistors T11, T21, and inverted to the other one; it may be applied to a gate terminal in each case. The second transistors T12, T22 118, 120 are designed as native transistors and the gate terminal of each is connected to the first supply potential VDD1. The native transistors are MOS transistors in which the channel doping approximately corresponds to the substrate doping so that the threshold voltage of the transistor is approximately 0 V. The input stage is formed by fifth transistors T15 122 and T25 124. The fifth transistors T15, T25 are designed as p-channel transistors and are cross-coupled with each other, i.e., the gate terminal of each fifth transistor T15 122 is connected to a source terminal of the other fifth transistor T25 124. At the source terminal of the fifth transistors T15, T25, the output signal out on the line 108 can be picked off once as a direct, and once as an inverted output signal outq on line 126. A potential difference of the first operating voltage range I can be limited via a first clamping circuit CL1 130. The same is provided for a potential difference of the second operating voltage range with a second clamping circuit CL2 132.

By using native transistors as the second transistors T12, T22 in the cascade circuits of input stages 110, 112, it is possible to configure the first transistors T11, T21 114, 116 technologically for first operating voltage range I and prevent, with the help of the native transistors T12, T22, stressing the drain circuits of the first transistors with a large potential difference between the second operating potential VDD2 and the first supply potential VSS1. The native transistors T12, T22 can be technologically configured for the second operating voltage range II, nevertheless having a threshold voltage Vₜₕ which can be reached in the first operating voltage range I.

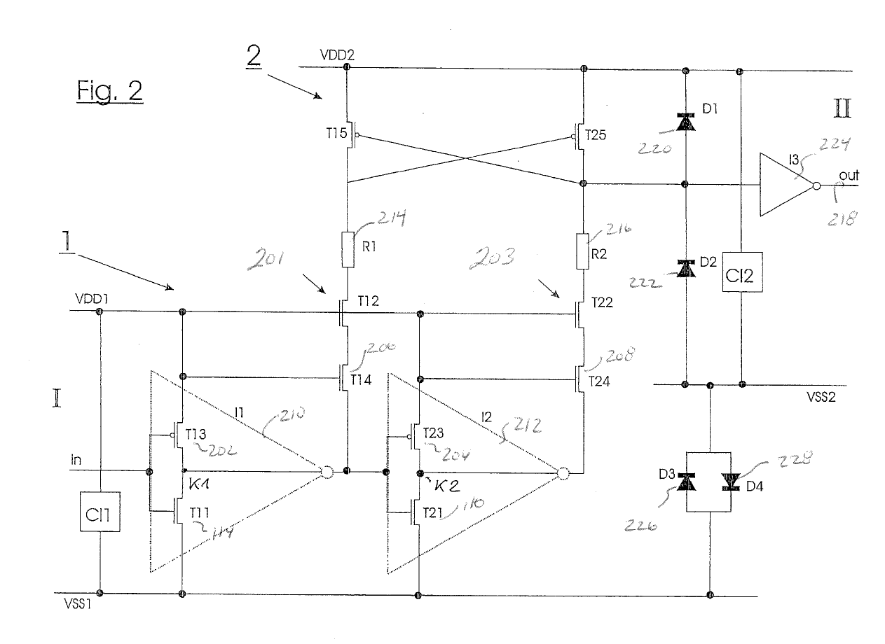

FIG. 2 shows the level shifter of FIG. 1 wherein the circuit shown in the latter is extended with different elements. Identical components are labeled the same way as in FIG. 1.

Each of input stages 201, 203 are extended with a third transistor T13, T23 202, 204 and a fourth transistor T14, T24 206, 208. The third transistor T13, T23 202, 204 is configured as a p-channel transistor and is connected between a drain terminal of the first transistor T11, T21 114, 116 and first supply potential VDD1. The input signal of the first transistor T11, T21 114, 116 is thus supplied to a gate terminal of the third transistor T13, T23 202, 204 in such a way that the first transistor T11, T21 114, 116 and third transistor T13, T23 202, 204 are connected as inverters. The input signal in on the line 106 is supplied to a first inverter I1 210 configured this way whereas the output signal of the first inverter I1 210 is supplied to a second inverter I2 212. The drain terminals of the first transistors T11, T21 114, 116 clamp to the first supply potential VDD1 via the third transistors T13, T23 202, 204 designed as p-channel transistors.

To prevent leakage currents between the second supply voltage range and the first supply voltage range, the fourth transistors T14, T24 206, 208 are connected in gate circuit between the first transistors T11, T21 114, 116 and the second transistors T12, T22 202, 204 and connected to first supply potential VDD1.

For limiting current flow, a first resistor R1 214 and a second resistor R2 216 are located between the input circuit 102 and output circuit 104. The resistors R1, R2 limit current peaks in case of electrostatic discharge thus preventing, together with other circuit components, damage to the level shifter in cases of electrostatic discharge. In order to limit the output signal out on the line 218 to the second operating voltage range II, a first clamping diode D1 220 and a second clamping diode D2 222 are provided. The clamping diodes D1, D2 are situated between the tap for output signal out on the line 218 and the second operating potential VDD2 as well as between the tap for the output signal out on the line 218 and second ground potential VSS2. A third inverter I3 224 can be provided on the output side in order to make use of the full voltage excursion of the second operating voltage range II. In order to avoid great potential differences between the first ground potential VSS1 and the second ground potential VVS2, third and fourth diodes D3, D4 226, 228 are provided between these two potentials which are connected antiparallel. The diodes D3, D4 make charge equalization between the ground potentials VSS1 and VSS2 possible thereby avoiding high voltages.

Although the present invention has been illustrated and described with respect to several preferred embodiments thereof, various changes, omissions and additions to the form and detail thereof, may be made therein, without departing from the spirit and scope of the invention.

What is claimed is:

1. A level shifter for converting an input signal (in) from a first operating voltage range (I) having a first ground potential (VSS1) and a first operating potential (VDD1) into an output signal (out) in a second operating voltage range (II) having a second ground potential (VSS2) and a second operating potential (VDD2) comprising: having an input circuit that receives the input signal and an output circuit that provides the output signal,
wherein the input circuit has at least one native transistor.

2. The level shifter of claim 1, wherein the input circuit has two input stages connected in parallel each of which has at least one native transistor.

3. The level shifter of claim 2, wherein the input stages are designed as cascode circuits.

4. The level shifter of claim 3, wherein the cascode circuits have a first transistor (T11, T21) and a second transistor (T12, T22), the first transistor (T11, T21) being suitable for the first operating voltage range (I) and the second transistor (T12, T22) being suitable for the second operating voltage range (II) and being configured as a native transistor.

5. The level shifter of claim 4, wherein a clamping circuit is situated between a connection node between the first transistor (T11, T21) and the second transistor (T12, T22) and the first supply potential (VDD1).

6. The level shifter of claim 5, wherein the clamping circuit comprises a third transistor (T13, T23) which is provided for the first operating voltage range (I).

7. The level shifter of claim 5, wherein a diode is connected between the connection nodes (K1, K2) and the first supply potential (VDD1) for clamping.

8. The level shifter of claim 3, wherein the cascode circuits comprise a fourth transistor (T14, T24) which is connected between the first transistor (T11, T21) and the second transistor (T12, T22).

9. The level shifter of claim 8,
wherein the input circuit and/or the output circuit comprise protective circuits (C11, C12, D1, D2, D3, D4) against electrostatic damage.

10. The level shifter of claim 8, wherein two diodes (D3, D4) connected in antiparallel are provided between the first ground potential (VSS1) and the second ground potential (VSS2).

11. The level shifter of claim 10, wherein resistors (R1, R2) are provided between the input circuit and the output circuit for current limiting.

12. The level shifter of claim 3, wherein there is a difference between the first operating potential (VDD1) and the first ground potential (VSS1) in the range of a threshold voltage (Vth11, Vth21) of the first transistor (T11, T21).

13. The level shifter of claim 1, wherein the level shifter is formed using MOS transistors.

14. The level shifter of claim 13, wherein the output circuit comprises two cross-coupled MOS transistors.
